(19) United States
(12) Patent Application Publication
(10) Pub. No.: US 2025/0038480 A1
(43) Pub. Date: Jan. 30, 2025

(54) BALANCED OUTPUT, DUAL-GAIN, HYBRID INTEGRATED DIODE LASER

(71) Applicant: LioniX International BV, Enschede (NL)

(72) Inventors: Randy te MORSCHE, Wierden (NL); Chris Gerardus Hermanus ROELOFFZEN, Weerselo (NL); Ahmad Wasfi MOHAMMAD, Enschede (NL); Dimitri GESKUS, Enschede (NL); René Gerrit HEIDEMAN, Oldenzaal (NL)

(21) Appl. No.: 18/778,378

(22) Filed: Jul. 19, 2024

Related U.S. Application Data
(60) Provisional application No. 63/528,788, filed on Jul. 25, 2023.

(51) Int. Cl. H01S 5/14; G02B 6/12; G02B 6/293; G02F 1/21; H01S 5/0687; H01S 5/10

(52) U.S. Cl. CPC H01S 5/142; G02B 6/12019; G02B 6/2934; G02F 1/212; H01S 5/0687; H01S 5/1032; G02B 2006/12061; G02B 2006/12121

(57) ABSTRACT

An integrated diode laser having lower total noise power at its outlet is realized by positioning a Mach-Zehnder interferometer in the optical path between two micro-ring resonators of a Vernier filter.

### STATEMENT OF RELATED CASE

This specification claims priority of U.S. Pat. App. 63/528,788, filed Jul. 25, 2023 and which is incorporated by reference herein.

### TECHNICAL FIELD

The present disclosure relates to photonic integrated circuits and, more particularly, to hybrid integrated diode lasers.

### BACKGROUND

A known design for an external cavity, hybrid, integrated diode laser 100 having two gain sections is depicted in FIG. 1. Laser 100 (see, U.S. Pat. No. 11,320,587, incorporated by reference herein) includes two gain sections 102A and 102B, and a planar lightwave circuit (PLC) 105 comprising optical waveguides and filters, all disposed on substrate 101. PLC 105 includes phase control elements 104A and 104B, Vernier filter 106 comprising two tunable micro-ring resonators (MRRs) 108 and 110, balanced path-length Mach-Zehnder interferometers (MZI) 112A and 112B, and phase control element 104E.

Vernier filter 106 selects one of the laser cavity modes. Phase control elements 104A or 104B tune the wavelength of laser 100, and optimize the output power by aligning a longitudinal cavity mode with the transmission maximum of Vernier filter 106.

MZI 112A includes two, 2×2 couplers 114A, and MZI 112B has two, 2×2 couplers 114B. Also, MZI 112A and MZI 112B include respective phase control elements 104C and 104D (each arm of each MZI includes a phase control element for redundancy, but only one phase control element for MZI is necessary assuming that it can provide full 360 degrees of phase control).

MZI 112A functions as a tunable cavity output coupler and, as such, is the power tap of the laser cavity for both clockwise and counterclockwise propagating fields. MZI 112B functions as a light (power) combiner, combining the two output fields from MZI 112A. The two MZIs 112A and 112B define a third MZI 112C. MZI 112C includes phase control element 104E, which is located between MZI 112A and MZI 112B. Phase control element 104E, together with MZI 112B (“the output MZI”), combine the light from the two waveguides (of MZI 112B) and direct it to output ports 116A and/or 116B. By appropriately setting the phase in phase shifter 104E, light will be directed to the desired output port 116A or 116B.

### SUMMARY

The present invention provides an integrated diode laser having lower total noise power at its outlet, relative to the integrated diode laser of the prior art. In accordance with the illustrative embodiment, this improvement is realized by altering the location of at least one MZI relative to the MRRs of the Vernier filter.

In prior-art laser 100, the amplified spontaneous emission (ASE) noise from the gain section 102B is coupled directly into the laser's output, due to the placement of the output coupler MZI (MZI 112A). In accordance with the present teachings, the output MZI is moved to a position between the MRRs of the Vernier filter. Consequently, the filtering of ASE from both gain sections is evenly distributed, resulting in a lower total noise power at the output of the laser. As a result, the integrated diode laser disclosed herein exhibits a reduction in relative intensity noise (RIN) and optical phase noise.

### BRIEF DESCRIPTION OF THE DRAWINGS

FIG. 1 depicts a conventional external cavity, integrated diode laser having two gain sections.

FIG. 2 depicts an external cavity, integrated diode laser in accordance with a first illustrative embodiment of the present invention.

FIG. 3 depicts an external cavity, integrated diode laser in accordance with a second illustrative embodiment of the present invention.

FIG. 4 depicts the optical power spectrum of the conventional integrated diode laser of FIG. 1.

FIG. 5 depicts the optical power spectrum of the integrated diode laser in accordance with the illustrative embodiment of the present invention.

FIG. 6 depicts RIN and phase noise spectra of the conventional integrated diode laser of FIG. 1.

FIG. 7 depicts RIN and phase noise spectra of the integrated diode laser in accordance with the illustrative embodiment of the present invention.

### DETAILED DESCRIPTION

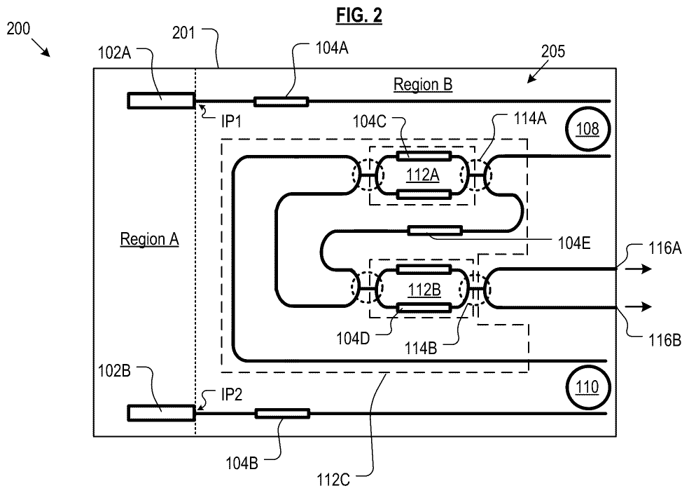

FIG. 2 depicts balanced output, dual gain, hybrid integrated diode laser 200 in accordance with the present teachings. In the illustrative embodiment, laser 200 includes two gain sections 102A and 102B disposed on region A of substrate 201, and planar lightwave circuit (PLC) 205, which comprises an arrangement of optical waveguides and filters, which is disposed on region B of substrate 201. Region A is etched down, relative to region B, to leave a recessed surface on which the gain sections are mounted. That depth is carefully controlled so that the gain channel lines up with the input facets. In some other embodiments, gain sections 102A and 102B are located on one or two separate submounts, and aligned with respect to input ports IP1 and IP2 of PLC 205. The one or two separate submounts are then glued, soldered, etc., to substrate 201.

Gain sections 102A and 102B are conventional elements suitable for providing optical gain for a light signal. For example, gain sections 102A and 102B can be a slab of indium phosphide (InP) that is configured to define a semiconductor optical amplifier. One facet of each of gain sections 102A and 102B is polished to define a mirror, which typically includes a high-reflectivity (HR) coating having a reflectivity of approximately 90%. Alternatively, the high-reflectivity facet of the gain sections can be cleaved, rather than polished, prior to being coated with an HR coating.

The opposite facet of each gain section 102A and 102B is coated with an anti-reflection coating configured to mitigate coupling loss between the gain section and the input ports IP1 and IP2 of PLC 205 disposed on substrate 203.

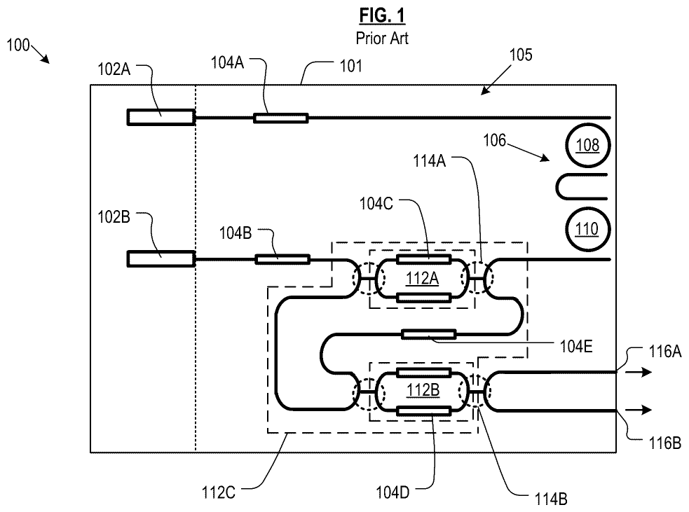

The waveguides of PLC 205 are arranged to define a low-loss optical circuit comprising phase control elements (phase shifters) 104A and 104B, a Vernier filter that includes two micro-ring resonators (MRRs) 108 and 110, and two balanced path-length Mach-Zehnder interferometers (MZI) 112A and 112B, two 2×2 couplers 114A and 114B associated with the respective MZIs, and phase control element (phase shifter) 104E. MZI 112A is part of the laser cavity; MZI 112B is outside of the laser cavity, and functions as a power combiner, as in laser 100 of FIG. 1. MZI 112B combines the (equal) power of the two output waveguides from MZI 112A, resulting in a factor of two increase in the laser output into either output 116A or 116B.

MZI 112A includes two, 2×2 couplers 114A, and MZI 112B has two, 2×2 couplers 114B. MZI 112A and MZI 112B include respective phase control elements (phase shifters) 104C and 104D, as in laser 100.

In the illustrative embodiment, the various waveguides of PLC 214 are multilayer-core waveguides (commonly referred to as TriPlex Waveguides™), as described in U.S. Pat. Nos. 7,146,087, 7,142,317, 9,020,317, and 9,221,074. Such waveguides have a core that includes a lower core layer comprising silicon nitride, a central core layer comprising silicon dioxide, and an upper core comprising silicon nitride. The three core layers are configured such that they collectively support single-mode propagation of a single optical mode. Such a waveguide structure is preferred in some embodiments because it enables low propagation loss over a wide spectral range, and can be readily tapered in one or two dimensions to control the shape of the mode field propagating through it, as described in U.S. Pat. No. 9,020,317. It will be understood however, that many alternative waveguide structures known to those skilled in the art can be used without departing from the scope of the present disclosure.

In laser 200, in accordance with the present teachings, MZI 112A is moved to a position in the optical path between MRRs 108 and 110 of the Vernier filter, with MZI 112B remaining connected to the outputs of MZI 112A. As such, the filtering of ASE from both gain sections 102A and 102B is evenly distributed, resulting in a lower total noise power at the outputs of the laser. Consequently, the integrated diode laser disclosed herein exhibits a reduction in relative intensity noise (RIN) and optical phase noise.

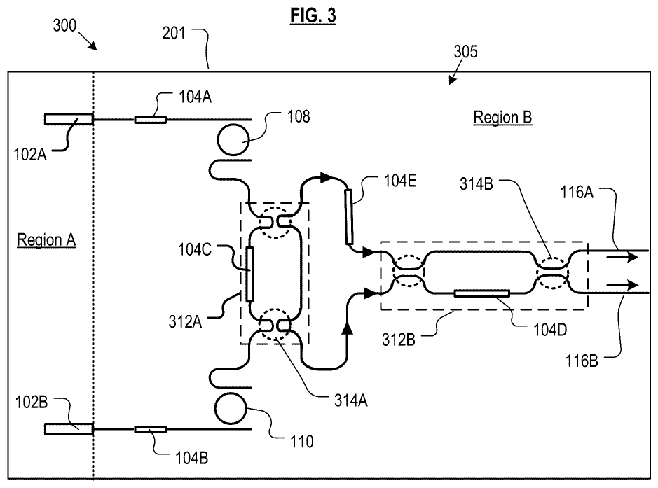

FIG. 3 depicts balanced output, dual gain, hybrid integrated diode laser 300 will full symmetry, in accordance with the present teachings. Like laser 200, output MZI 312A is moved to a position between MRRs 108 and 110 of the Vernier filter (i.e., MRRs 108 and 110).

The elements of laser 300 are the same as those of laser 200, but arranged somewhat differently. Laser 300 shows that with the correct symmetry, and unlike the more general layout of laser 200, all paths can have the same length.

More particularly, laser 300 includes two gain sections 102A and 102B disposed on region A of substrate 201, and planar lightwave circuit (PLC) 305, comprising an arrangement of optical waveguides and filters, disposed on region B of substrate 201. Like laser 200, the gain sections of laser 300 may alternatively be disposed on one or more separate submounts that are aligned with and attached to substrate 201.

The waveguides of PLC 305 are arranged to define a low-loss optical circuit comprising phase control elements 104A and 104B, a Vernier filter that includes two micro-ring resonators (MRRs) 108 and 110, two balanced path-length Mach-Zehnder interferometers (MZI) 312A and 312B, and phase control element 104E. MZI 312A is part of the laser cavity; MZI 312B is outside of the laser cavity, and functions as a power combiner, as in lasers 100 and 200.

MZI 312A includes two, 2×2 couplers 314A, and MZI 312B has two, 2×2 couplers 314B. MZI 312A and MZI 312B include respective phase control elements 104C and 104D, as in laser 100. The 2×2 couplers of FIG. 3 are depicted as being different from those of FIG. 2. Any of a variety of 2×2 couplers can be used for laser 200 of FIG. 2 and laser 300 of FIG. 3.

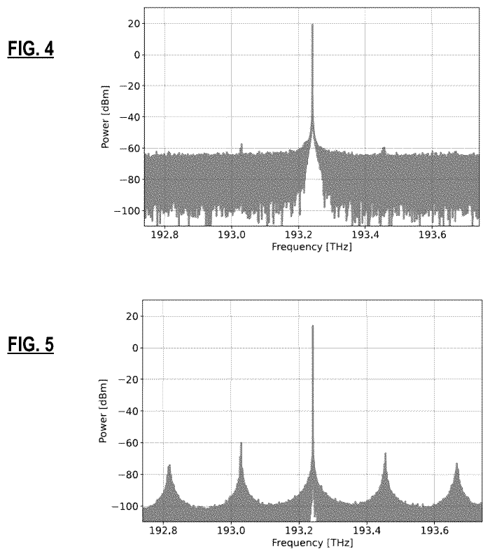

The performance of laser 200 was compared to the performance of conventional laser 100 using simulation software, commercially available from VPIphotonics and others. FIGS. 4 and 5 depict, for respective lasers 100 and 200, the resulting optical power spectrum in continuous wave operation at the output of each laser.

As depicted in FIGS. 4 and 5, a strong output signal appears at about 193.24 THz for both lasers. However, comparing these two figures shows that the noise floor of laser 200 in accordance with the present teachings is significantly lower than that of a conventional version of dual gain, hybrid integrated diode laser 100.

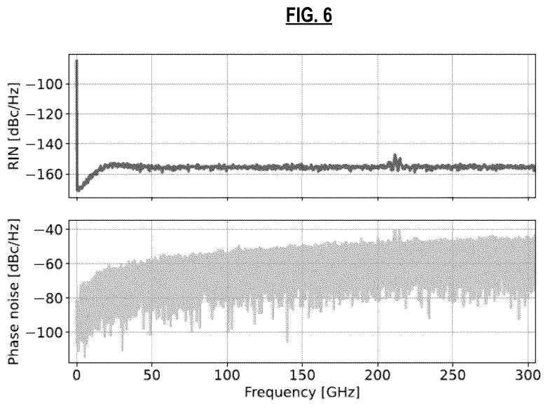

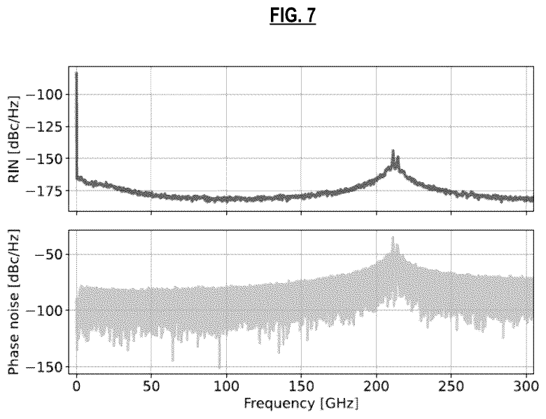

Additionally, the relative intensity noise (RIN) and the optical phase noise power spectral densities (PSDs) of laser 100 and laser 200 were calculated. FIG. 6 depicts RIN and PSD for laser 100, and FIG. 7 depicts these spectra for laser 200.

Consistent with the power-spectrum results, the noise at relatively higher frequencies (several GHZ) is significantly lowered for laser 200 relative to laser 100. For example, the RIN at 50 GHz is approximately −155 dBc/Hz for laser 100, which is lowered to about −175 dBc/Hz for laser 200. This demonstrates a significant improvement in noise performance of the dual-gain laser using balanced filtering of ASE noise from the two gain sections.

Summarizing, a dual gain, hybrid, integrated diode laser comprises: two gain sections; and a planar lightwave circuit optically coupled to the two gain sections, wherein the planar lightwave circuit includes: first and second phase control elements; a Vernier filter comprising first and second tunable micro-ring resonators (MRRs); first and second Mach-Zehnder interferometers (MZIs), and a third phase control element disposed between the first and second MZIs, characterized in that the first MZI is disposed in the optical path between the first MRR and the second MRR. In further embodiments of the invention, the dual gain, hybrid, integrated diode laser may further include any one or more of the following elements:
the first phase-control element is optically coupled to the first gain section;
the second phase-control element is optically coupled to the second gain section;
the first micro-ring resonator (MRR) is optically coupled to the first phase-control section;
the second micro-ring resonator (MRR) optically coupled to the second phase-control section;
the first Mach-Zehnder interferometer (MZI) has a first waveguide branch and a second waveguide branch;
the first MMR and the second MMR are optically coupled to the first waveguide branch of the first MZI;
the second MZI has a first waveguide branch and a second waveguide branch;
the second MZI is optically coupled to the second waveguide branch of the first MZI;
at least one output port, wherein the third phase control element and the second MZI combine light from the first and second waveguide branches of the second MZI into the at least one output port;
a first optical path length defined between the first gain section and the first MZI and a second optical path length defined between the second gain section and the first MZI are equal to one another;
the first MZI and the second MZI each include two, 2×2 couplers and at least one phase control element;
the first and second waveguide branches of each of the first MZI and the second MZI have a multi-layer core, wherein the core includes a lower core layer comprising silicon nitride, a central core layer comprising silicon dioxide, and an upper core comprising silicon nitride;
the first MZI and the second MZI are physically rotated with respect to one another by 90 degrees;
the first and second phase-control sections are operable to tune an operating wavelength of the dual gain, hybrid, integrated diode laser;
the first Mach-Zehnder interferometer has balanced optical path length;
the first Mach-Zehnder interferometer is disposed in a waveguide that optically couples the first MMR and the second MMR to one another;
the gain sections and the planar Lightwave circuit are disposed on a single substrate;
the gain sections and the planar Lightwave circuit are disposed on different submounts/substrates; and/or
the second MZI combines the power of the two output waveguides from the first MZI, resulting in a factor of two increase in the laser output.

It is to be understood that the disclosure teaches just one example of the illustrative embodiment and that many variations of embodiments in accordance with the present disclosure can easily be devised by those skilled in the art after reading this disclosure and that the scope of the present invention is to be determined by the following claims.

What is claimed is:

1. A dual gain, hybrid, integrated diode laser comprising:
first and second gain sections;
a planar lightwave circuit optically coupled to the first and second gain sections, the planar lightwave circuit including:
first and second phase control elements;
a Vernier filter comprising first and second tunable micro-ring resonators (MRRs);
first and second Mach-Zehnder interferometers (MZIs), and a third phase control element disposed between the first and second MZIs, characterized in that:
the first MZI is disposed in the optical path between the first MRR and the second MRR.

2. The dual gain, hybrid, integrated diode laser of claim 1 wherein each of the first MZI and the second MZI have first and second waveguide branches, and wherein each of the first and second waveguide branches of each of the first MZI and the second MZI have a multi-layer core, wherein the core includes a lower core layer comprising silicon nitride, a central core layer comprising silicon dioxide, and an upper core comprising silicon nitride.

3. The dual gain, hybrid, integrated diode laser of claim 1 wherein a first optical path length defined between the first gain section and the first MZI and a second optical path length defined between the second gain section and the first MZI are equal to one another.

4. The dual gain, hybrid, integrated diode laser of claim 1 wherein the first MZI and the second MZI each include two, 2×2 couplers, and at least one phase control element.

5. The dual gain, hybrid, integrated diode laser of claim 1 wherein the first and second phase-control elements are operable to tune an operating wavelength of the dual gain, hybrid, integrated diode laser.

6. The dual gain, hybrid, integrated diode laser of claim 1 wherein the first MZI functions as a power tap for the dual gain, hybrid integrated diode laser, and wherein the second MZI functions as a power combiner for the first MZI.

7. The dual gain, hybrid, integrated diode laser of claim 2 wherein second MZI is optically coupled to the second waveguide branch of the first MZI.

8. The dual gain, hybrid, integrated diode laser of claim 1 comprising at least one output port, wherein the third phase control element and the second MZI combine light from the first and second waveguide branches of the second MZI into the at least one output port.

9. A dual gain, hybrid, integrated diode laser comprising:
a first gain section;
a first phase-control section that is optically coupled to the first gain section;
a second gain section;
a second phase-control section that is optically coupled to the second gain section;
a first micro-ring resonator (MRR) optically coupled to the first phase-control section;
a second micro-ring resonator (MRR) optically coupled to the second phase-control section;
a first Mach-Zehnder interferometer (MZI) having a first waveguide branch and a second waveguide branch, wherein the first MMR and the second MMR are optically coupled to the first waveguide branch of the first MZI, and wherein the first MZI is disposed in an optical path between the first MMR and the second MMR;
a second MZI having a first waveguide branch and a second waveguide branch, wherein second MZI is optically coupled to the second waveguide branch of the first MZI, and wherein a phase shifter is disposed between the first MZI and the second MZI; and
at least one output port, wherein the phase shifter and the second MZI combine light from the first and second waveguide branches of the second MZI into the at least one output port.

10. The dual gain, hybrid, integrated diode laser of claim 9 wherein a first optical path length defined between the first gain section and the first MZI and a second optical path length defined between the second gain section and the first MZI are equal to one another.

11. The dual gain, hybrid, integrated diode laser of claim 9 wherein the first MZI and the second MZI each include two, 2×2 couplers and at least one phase control element.

12. The dual gain, hybrid, integrated diode laser of claim 9 wherein the first and second waveguide branches of each of the first MZI and the second MZI have a multi-layer core, wherein the core includes a lower core layer comprising silicon nitride, a central core layer comprising silicon dioxide, and an upper core comprising silicon nitride.

13. The dual gain, hybrid, integrated diode laser of claim 9 wherein the first and second phase-control sections are operable to tune an operating wavelength of the dual gain, hybrid, integrated diode laser.

14. A dual gain, hybrid, integrated diode laser comprising:
a first gain section and a second gain section;
phase-control sections for tuning an operating wavelength of the dual gain, hybrid, integrated diode laser;
a Vernier filter including a first micro-ring resonator (MRR) and a second MRR, wherein the first MRR receives light from the first gain section and the second MRR receives light from the second gain section;
a first Mach-Zehnder interferometer (MZI) having two waveguide branches, wherein the first MZI functions as a power tap for the laser, and wherein the first MZI is disposed in an optical path between the first MMR and the second MMR;
a second MZI having two waveguide branches, wherein the second MZI functions as a power combiner for the first MZI;
a phase shifter disposed between the first MZI and the second MZI; and
at least one output port, wherein the phase shifter and the second MZI combine light from the two waveguide branches of the second MZI into the at least one output port.

15. The dual gain, hybrid, integrated diode laser of claim 14 wherein the first Mach-Zehnder interferometer has balanced optical path length.

16. The dual gain, hybrid, integrated diode laser of claim 14 wherein the first Mach-Zehnder interferometer is disposed in a waveguide that optically couples the first MMR and the second MMR to one another.

17. The dual gain, hybrid, integrated diode laser of claim 14 wherein all optical paths from the first gain section and the second gain section to the at least first MZI have equal lengths.

18. The dual gain, hybrid, integrated diode laser of claim 14 wherein the first MZI and the second MZI each include two, 2×2 couplers and at least one phase control element.

19. The dual gain, hybrid, integrated diode laser of claim 14 wherein the two waveguide branches of each of the first MZI and the second MZI have a multi-layer core, wherein the core includes a lower core layer comprising silicon nitride, a central core layer comprising silicon dioxide, and an upper core comprising silicon nitride.
